(19) United States
(12) Patent Application Publication
(10) Pub. No.: US 2026/0279458 A1
(43) Pub. Date: Sep. 17, 2026

(54) SEMICONDUCTOR STORAGE DEVICE

(71) Applicant: Kioxia Corporation, Tokyo (JP)

(72) Inventor: Takahiro SUGIMOTO, Yokohama Kanagawa (JP)

(21) Appl. No.: 19/319,626

(22) Filed: Sep. 4, 2025

(30) Foreign Application Priority Data
Mar. 12, 2025 (JP) 2025-039570

(51) Int. Cl. G11C 16/26

(52) U.S. Cl. CPC G11C 16/26

(57) ABSTRACT

A semiconductor storage device includes an input/output pad, a memory cell array including a plurality of memory cells, an input/output circuit provided between the input/output pad and the memory cell array, a sense amplifier connected to the memory cell array, a bidirectional data bus including a plurality of data wirings connecting the input/output circuit and the sense amplifier, and a sequencer configured to control the input/output circuit, the memory cell array, the sense amplifier, and the bidirectional data bus. Each of the data wirings is provided with a repeater buffer circuit. The repeater buffer circuit includes a first repeater buffer and a second repeater buffer connected in parallel to the first repeater buffer. The sequencer is configured to transmit a switching signal for independently controlling each of the first repeater buffer and the second repeater buffer to be enabled or disabled.

### CROSS-REFERENCE TO RELATED APPLICATIONS

This application is based upon and claims the benefit of priority from Japanese Patent Application No. 2025-039570, filed Mar. 12, 2025, the entire contents of which are incorporated herein by reference.

### FIELD

Embodiments described herein relate generally to a semiconductor storage device.

### BACKGROUND

A semiconductor storage device including a non-volatile memory is known.

### BRIEF DESCRIPTION OF THE DRAWINGS

FIG. 1 is a block diagram illustrating a configuration example of a memory system including a semiconductor storage device according to an embodiment.

FIG. 2 is a block diagram illustrating a configuration of the semiconductor storage device according to the embodiment.

FIG. 3A illustrates an example of a command sequence for instructing a write operation in a non-volatile memory.

FIG. 3B illustrates an example of a command sequence related to the write operation in the non-volatile memory.

FIG. 4A illustrates an example of a command sequence for instructing a read operation in the non-volatile memory.

FIG. 4B illustrates an example of a command sequence related to the read operation in the non-volatile memory.

FIG. 5A illustrates a block diagram illustrating a part of the configuration of the semiconductor storage device according to the embodiment.

FIG. 5B is a block diagram illustrating a configuration of a relay area provided in a path of a bidirectional data bus of the semiconductor storage device according to the embodiment.

FIG. 6 is a circuit diagram illustrating an example of a bidirectional transmission circuit of the semiconductor storage device according to the embodiment.

FIG. 7 is a circuit diagram illustrating another example of the bidirectional transmission circuit of the semiconductor storage device according to the embodiment.

FIG. 8A is a circuit diagram of a repeater buffer circuit of a first configuration example in the semiconductor storage device according to the embodiment.

FIG. 8B is a circuit diagram of a repeater buffer circuit according to a modification of the first configuration example.

FIG. 9A is a circuit diagram of a repeater buffer circuit of a second configuration example in the semiconductor storage device according to the embodiment.

FIG. 9B is a circuit diagram of a repeater buffer circuit according to a modification of the second configuration example.

### DETAILED DESCRIPTION

Embodiments provide a semiconductor storage device capable of switching a transmission speed and preventing an off-leakage current.

In general, according to one embodiment, a semiconductor storage device includes: an input and output pad; a memory cell array including a plurality of memory cells; an input and output circuit provided between the input and output pad and the memory cell array; a sense amplifier connected to the memory cell array; a bidirectional data bus including a plurality of data wirings connecting the input and output circuit and the sense amplifier; and a sequencer configured to control the input and output circuit, the memory cell array, the sense amplifier, and the bidirectional data bus. Each of the data wirings is provided with a repeater buffer circuit. The repeater buffer circuit includes a first repeater buffer and a second repeater buffer connected in parallel to the first repeater buffer. The sequencer is configured to transmit a switching signal for independently controlling each of the first repeater buffer and the second repeater buffer to be enabled or disabled.

Hereinafter, an embodiment will be described with reference to the drawings. In illustrations of the drawings to be described hereinafter, the same or similar parts are denoted by the same or similar reference signs. The drawings are schematic. The embodiment described below is an example of devices and methods for embodying the technical idea disclosed herein, and is not limited to the specific materials, shapes, structures, arrangements, and the like of components described herein. Various modifications can be made to the embodiment.

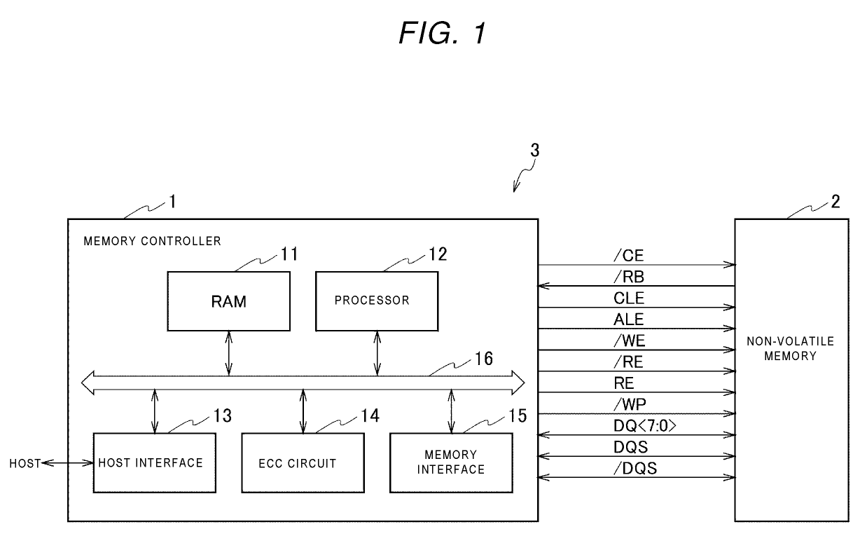

A semiconductor storage device according to an embodiment is, for example, a non-volatile memory 2 provided in a memory system 3 illustrated in FIG. 1. The non-volatile memory 2 is a semiconductor memory that stores data in a non-volatile manner. The non-volatile memory 2 includes, for example, a NAND flash memory. A memory controller 1 controls operations of the non-volatile memory 2. A host is, for example, an electronic device such as a personal computer or a mobile terminal.

First, the memory system 3 illustrated in FIG. 1 will be described. It is noted that a signal DQ <7:0> means a set of signals DQ <0>, DQ <1>, ..., and DQ <7>, each of which is a 1-bit signal in the following description. The signal DQ <7:0> is an 8-bit signal.

The memory controller 1 receives an instruction from the host and controls the non-volatile memory 2 based on the received instruction. Specifically, the memory controller 1 writes data instructed by the host to be written to the non-volatile memory 2, reads data instructed by the host to be read from the non-volatile memory 2, and transmits the data to the host. The memory controller 1 specifies a non-volatile memory cell in the non-volatile memory 2 to which the data is to be written. Hereinafter, the non-volatile memory cell in the non-volatile memory 2 is also referred to as a "memory cell".

The memory controller 1 and the non-volatile memory 2 transmit and receive signals according to interface standards of the memory controller 1 and the non-volatile memory 2 via individual signal lines. The signals transmitted and received between the memory controller 1 and the non-volatile memory 2 include signals /CE, /RB, CLE, ALE, /WE, /RE, RE, /WP, DQ <7:0>, DQS, /DQS, and the like.

The signal /CE is a chip enable signal for enabling the non-volatile memory 2. The signal /RB is a ready/busy signal for indicating whether the non-volatile memory 2 is in a ready state (a state of receiving instructions from an outside) or a busy state (a state of not receiving instructions from the outside). The signal CLE is a command latch enable signal for notifying the non-volatile memory 2 that the signal DQ <7:0> transmitted to the non-volatile memory 2 while the signal CLE is at a high (H) level is a command. The signal ALE is an address latch enable signal for notifying the non-volatile memory 2 that the signal DQ <7:0> transmitted to the non-volatile memory 2 while the signal ALE is at the H level is an address. The signal /WE is a write enable signal for instructing the non-volatile memory 2 to capture the signal DQ <7:0> to be transmitted to the non-volatile memory 2. In a single data rate (SDR) mode, it is instructed to capture the signal DQ <7:0> as a command, an address, or data to be transmitted to the non-volatile memory 2 at a rising edge of the signal /WE. In a double data rate (DDR) mode, it is instructed to capture the signal DQ <7:0> as a command or an address to be transmitted to the non-volatile memory 2 at the rising edge of the signal /WE. The signal /WE is asserted every time the non-volatile memory 2 receives a command, an address, and data from the memory controller 1.

The signal /RE is a read enable signal for instructing the memory controller 1 to read the signal DQ <7:0> from the non-volatile memory 2. The signal RE is a complementary signal of the signal /RE. For example, the signals /RE and RE are used to control a timing at which the non-volatile memory 2 outputs the signal DQ <7:0>. More specifically, in the single data rate mode, it is instructed to output the signal DQ <7:0> as data to the non-volatile memory 2 at a falling edge of the signal /RE. In the double data rate mode, it is instructed to output the signal DQ <7:0> as data to the non-volatile memory 2 at the falling edge and the rising edge of the signal /RE. The signal /WP is a write protect signal for instructing the non-volatile memory 2 to prohibit writing of data.

The signal DQ <7:0> is data transmitted and received between the non-volatile memory 2 and the memory controller 1. The signal DQ <7:0> includes a command CMD, an address ADD, and data DAT. The data DAT includes data (hereinafter, also referred to as "write data") to be written to the non-volatile memory and data (hereinafter also referred to as "read data") read from the non-volatile memory. The signal DQS is a data strobe signal used to control an operation timing of the non-volatile memory 2 related to the signal DQ <7:0>. The signal /DQS is a complementary signal of the signal DQS. The signals DQS and /DQS are generated based on, for example, the signals RE and /RE. More specifically, in the double data rate mode, the non-volatile memory 2 is instructed to capture the signal DQ <7:0> as data at a falling edge and a rising edge of the signal DQS. In the double data rate mode, the signal DQS is generated based on the falling edge and the rising edge of the signal /RE, and is output from the non-volatile memory 2 together with the signal DQ <7:0> as data.

The memory controller 1 includes a RAM 11, a processor 12, a host interface 13, an ECC circuit 14, and a memory interface 15. The RAM 11, the processor 12, the host interface 13, the ECC circuit 14, and the memory interface 15 are connected to one another via a bus 16.

The RAM 11 temporarily stores the data received from the host before the data is stored in the non-volatile memory 2, and temporarily stores the data read from the non-volatile memory 2 before the data is transmitted to the host. The RAM 11 is, for example, a general-purpose semiconductor memory such as a static random access memory (SRAM) or a dynamic random access memory (DRAM).

The processor 12 controls the entire operation of the memory controller 1. The processor 12 is, for example, a central processing unit (CPU) or a micro processing unit (MPU). For example, the processor 12 issues a read instruction to the non-volatile memory 2 in response to, for example, a read instruction of data that is received from the host. This operation is the same in the case of writing of data. The processor 12 determines, for the data stored in the RAM 11, a storage region (a memory region) in the non-volatile memory 2. The processor 12 has a function of executing various calculations on the read data from the non-volatile memory 2.

The host interface 13 is connected to the host and executes processing according to an interface standard with the host. The host interface 13 transfers, for example, instructions and data received from the host to the processor 12. The host interface 13 transmits to the host, data read from the non-volatile memory 2, a response from the processor 12, and the like.

The ECC circuit 14 encodes data stored in the RAM 11 to generate a code word. The ECC circuit 14 decodes the code word read from the non-volatile memory 2.

The memory interface 15 is connected to the non-volatile memory 2 via a bus and executes communication with the non-volatile memory 2. The memory interface 15 transmits the command CMD, the address ADD, and the write data to the non-volatile memory 2 according to an instruction from the processor 12. The memory interface 15 receives the read data from the non-volatile memory 2.

FIG. 1 illustrates a configuration example in which the memory controller 1 includes the ECC circuit 14 and the memory interface 15. However, the ECC circuit 14 may be built into the memory interface 15. The ECC circuit 14 may be built into the non-volatile memory 2.

When receiving a write instruction from the host, the memory system 3 operates as follows. The processor 12 temporarily stores the data to be written in the RAM 11. The processor 12 reads the data stored in the RAM 11 and inputs the data to the ECC circuit 14. The ECC circuit 14 encodes the input data and inputs the code word to the memory interface 15. The memory interface 15 writes the input code word into the non-volatile memory 2.

When a read instruction is received from the host, the memory system 3 operates as follows. The memory interface 15 inputs the code word read from the non-volatile memory 2 to the ECC circuit 14. The ECC circuit 14 decodes the input code word and stores decoded data in the RAM 11. The processor 12 transmits the data stored in the RAM 11 to the host via the host interface 13.

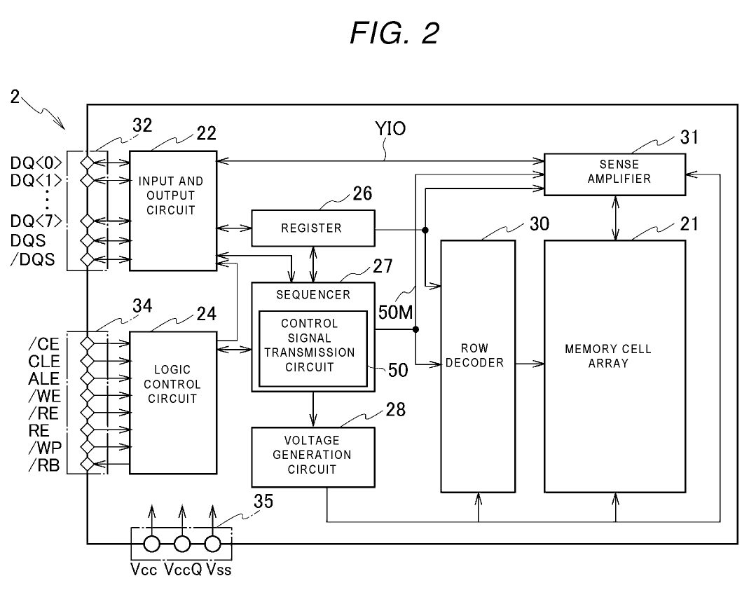

FIG. 2 is a block diagram illustrating a configuration example of the non-volatile memory 2. The non-volatile memory 2 includes a memory cell array 21, an input and output circuit 22, a logic control circuit 24, a register 26, a sequencer 27, a voltage generation circuit 28, a row decoder 30, a sense amplifier 31, and a control signal transmission circuit 50. The non-volatile memory 2 further includes an input and output pad group 32, a logic control pad group 34, and a power input terminal group 35.

The memory cell array 21 includes a plurality of memory cells associated with word lines and bit lines. The memory cell array 21 includes, for example, a NAND string.

The input and output circuit 22 transmits and receives the signal DQ <7:0> and the signals DQS and /DQS to and from the memory controller 1. The input and output circuit 22 transfers the command CMD and the address ADD in the signal DQ <7:0> to the register 26. The input and output circuit 22 transmits and receives the write data and the read data to and from the sense amplifier 31.

The logic control circuit 24 receives the signals /CE, CLE, ALE, /WE, /RE, RE, /WP, and /RB from the memory controller 1. The logic control circuit 24 transfers the signal /RB to the memory controller 1 to notify a state of the non-volatile memory 2 to the outside.

The register 26 stores the command CMD and the address ADD. The register 26 transfers the address ADD to the row decoder 30 and the sense amplifier 31 and also transfers the command CMD to the sequencer 27.

The sequencer 27 receives the command CMD and controls the entire non-volatile memory 2 according to a sequence based on the received command CMD. The sequencer 27 supplies, for example, a control signal to the input and output circuit 22. For example, the sequencer 27 supplies control signals to the row decoder 30 and the sense amplifier 31 via a control signal wiring 50M. For example, a plurality of the control signal wirings 50M may be provided. In this case, a plurality of types of control signals are supplied from the sequencer 27 to the row decoder 30 and/or the sense amplifier 31 via the plurality of control signal wirings 50M, respectively.

The voltage generation circuit 28 generates voltages required for operations such as writing of data, reading of data, and erasing of data based on an instruction from the sequencer 27. Based on the address from the register 26, various voltages are supplied from the voltage generation circuit 28 to the row decoder 30, the sense amplifier 31, and the memory cell array 21.

The row decoder 30 receives a block address and a row address in the address ADD from the register 26. The row decoder 30 selects a block based on a block address and selects a word line based on the row address.

The sense amplifier 31 is connected to the memory cell array 21. At the time of reading of data, the sense amplifier 31 senses the read data that is read from the memory cell to the bit line, and transfers the sensed read data to the input and output circuit 22. At the time of the writing of data, the sense amplifier 31 transfers the write data to the memory cell via the bit line.

The data transfer between the input and output circuit 22 and the sense amplifier 31 is performed via a bidirectional data bus YIO. The bidirectional data bus YIO includes a plurality of data wirings connected between the input and output circuit 22 and the sense amplifier 31. Data to be written to the non-volatile memory 2 and data read from the non-volatile memory 2 propagate through the bidirectional data bus YIO.

The control signal transmission circuit 50 generates a clock signal used for the operation of the non-volatile memory 2 based on the signals /RE and RE supplied from the memory controller 1. In FIG. 2, the control signal transmission circuit 50 is illustrated as a part of the sequencer 27. However, the control signal transmission circuit 50 may be implemented as, for example, a part of the input and output circuit 22 and/or the logic control circuit 24. In addition, the control signal transmission circuit 50 may be implemented as a circuit different from any of the sequencer 27, the input and output circuit 22, and the logic control circuit 24.

To transmit and receive signals including data between the non-volatile memory 2 and the memory controller 1, the input and output pad group 32 includes a plurality of terminals (pads) corresponding to the signal DQ <7:0> and the signals DQS and /DQS.

To transmit and receive signals between the non-volatile memory 2 and the memory controller 1, the logic control pad group 34 includes a plurality of terminals (pads) corresponding to the signals /CE, CLE, ALE, /WE, /RE, RE, /WP, and /RB.

To supply various operation power to the non-volatile memory 2 from the outside, the power input terminal group 35 includes a plurality of terminals to which a first power supply voltage Vcc, a second power supply voltage VccQ, and a ground voltage Vss as a third power supply voltage are input. The first power supply voltage Vcc is a circuit power supply voltage generally supplied from the outside as the operation power supply. The first power supply voltage Vcc is a power supply voltage supplied to a core portion of a semiconductor chip (hereinafter, simply referred to as a "chip") in which the non-volatile memory 2 is formed, and is, for example, 2.5 V. The second power supply voltage VccQ is used when signals are transmitted and received between the memory controller 1 and the non-volatile memory 2, and is, for example, 1.2 V.

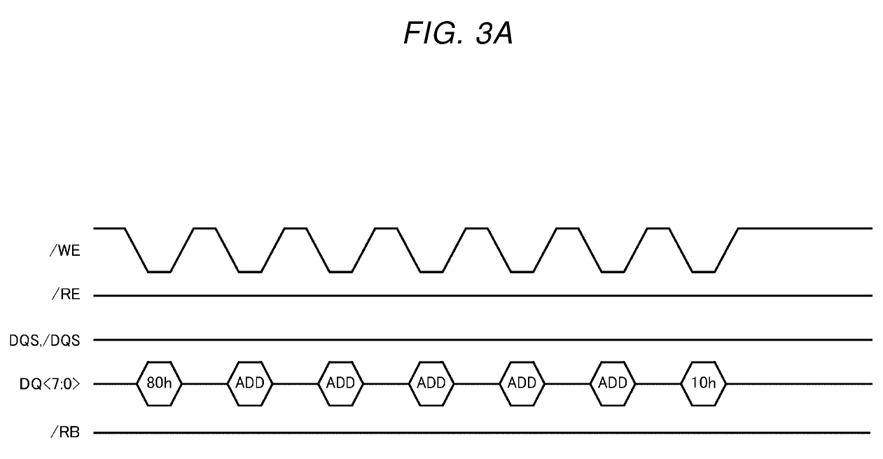

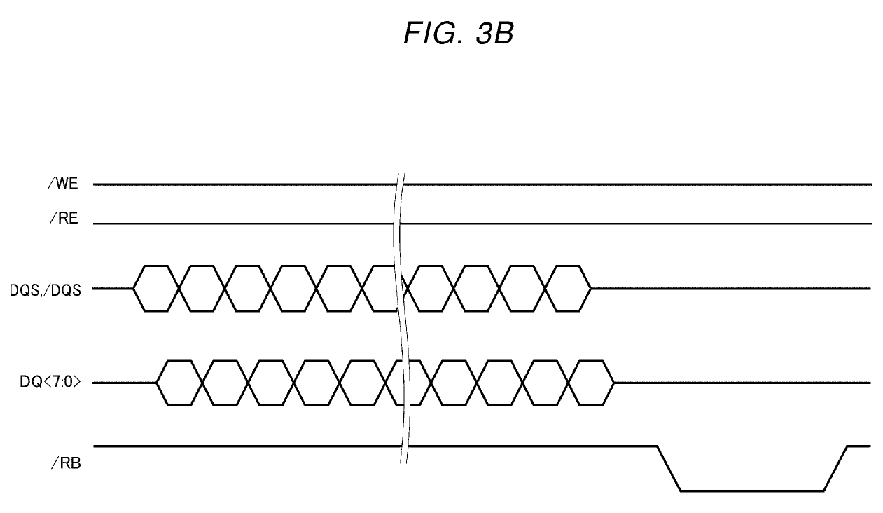

FIG. 3A illustrates an example of a command sequence for instructing a write operation (hereinafter also referred to as a "data-in operation") of the non-volatile memory 2. FIG. 3B illustrates an example of a command sequence related to the data-in operation.

As illustrated in FIG. 3A, in the data-in operation, the memory controller 1 issues a command set for instructing the data-in operation to the non-volatile memory 2 while toggling the signal /WE. The command set for instructing the data-in operation includes, for example, a read command "80h", the addresses ADD over five cycles, and a command "10h". The read command "80h" is a command for instructing writing of data to a user data area in the memory cell array 21. The command "10h" is a command for instructing a start of the data-in operation.

After the command "10h", as illustrated in FIG. 3B, the memory controller 1 transfers data to be written to the memory cell array 21 to the non-volatile memory 2 as the signal DQ <7:0>. When the data to be written is transferred to the non-volatile memory 2, the memory controller 1 toggles the signals DQS and /DQS in synchronization with the signal DQ <7:0> and transfers the signals to the non-volatile memory 2.

When receiving the data to be written, the non-volatile memory 2 starts the write operation to the user data area in the memory cell array 21, sets the signal /RB to an L level, and notifies the memory controller 1 that the non-volatile memory 2 is in the busy state. When the write operation is completed, the non-volatile memory 2 sets the signal /RB to the H level and notifies the memory controller 1 that the non-volatile memory 2 is in the ready state.

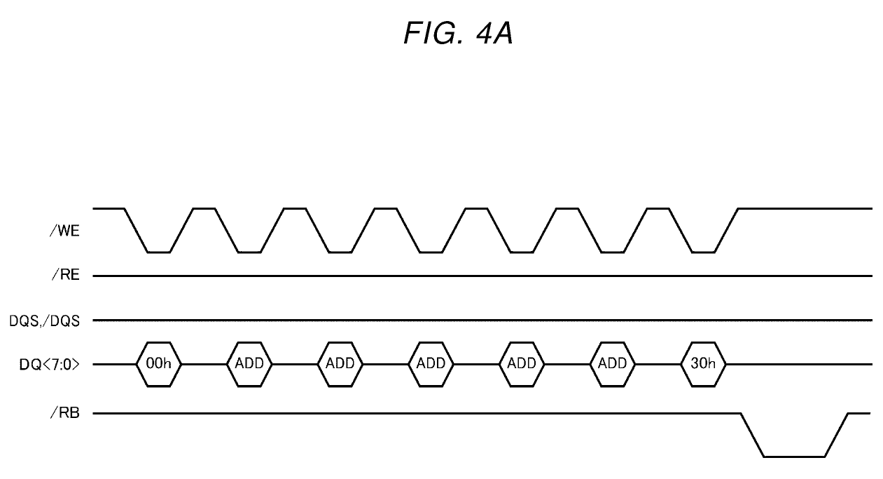

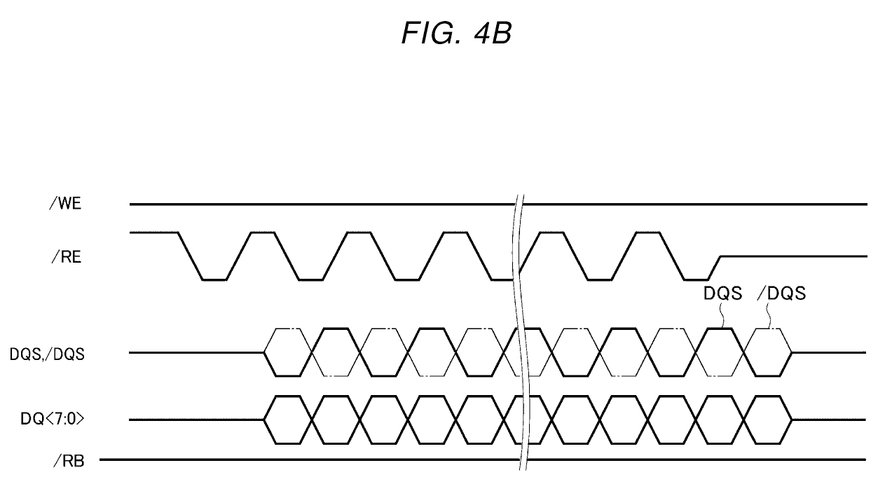

FIG. 4A illustrates an example of a command sequence for instructing a read operation (hereinafter also referred to as a "data-out operation") of the non-volatile memory 2. FIG. 4B illustrates an example of a command sequence related to the data-out operation.

As illustrated in FIG. 4A, in the data-out operation, the memory controller 1 issues a command set for instructing the data-out operation to the non-volatile memory 2 while toggling the signal /WE. The command set for instructing the data-out operation includes, for example, a read command "00h", the addresses ADD over five cycles, and a command "30h". The read command "00h" is a command for instructing reading of data from the memory cell array 21 of the non-volatile memory 2. The command "30h" is a command for instructing a start of the data-out operation. When receiving the command , the non-volatile memory 2 starts the read operation of data from the memory cell array 21, sets the signal /RB to the L level, and notifies the memory controller 1 that the non-volatile memory 2 is in the busy state. When the read operation is completed, the non-volatile memory 2 sets the signal /RB to the H level and notifies the memory controller 1 that the non-volatile memory 2 is in the ready state.

After confirming that the non-volatile memory 2 is in the ready state, the memory controller 1 toggles the signals /RE and RE as illustrated in FIG. 4B. The non-volatile memory 2 transfers the read data to the memory controller 1 as the signal DQ <7:0> in synchronization with the signals /RE and RE. The non-volatile memory 2 toggles the signals DQS and /DQS in synchronization with the signal DQ <7:0> and transfers the signals to the memory controller 1.

It is noted that after confirming that the non-volatile memory 2 is in the ready state, the memory controller 1 may issue the command set for instructing the data-out operation to the non-volatile memory 2 while toggling the signal /WE. The command set for instructing the data-out operation includes, for example, a data-out command "05h", the addresses ADD over five cycles, and a command "E0h". In this case, the memory controller 1 toggles the signals /RE and RE after a predetermined period of time elapses after transmitting the command "E0h" to the non-volatile memory 2. The non-volatile memory 2 transfers the read data to the memory controller 1 as the signal DQ <7:0> in synchronization with the signals /RE and RE. The non-volatile memory 2 toggles the signals DQS and /DQS in synchronization with the signal DQ <7:0> and transfers the signals to the memory controller 1.

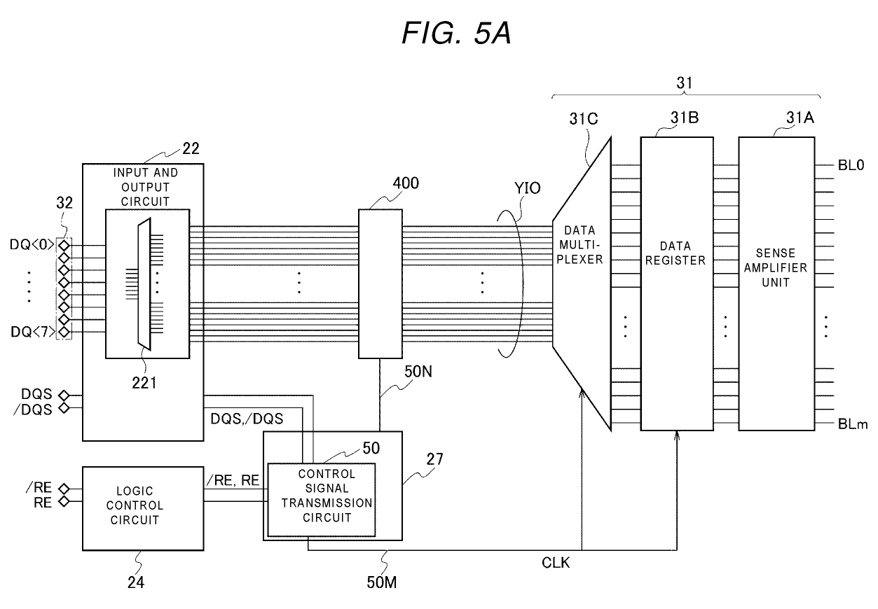

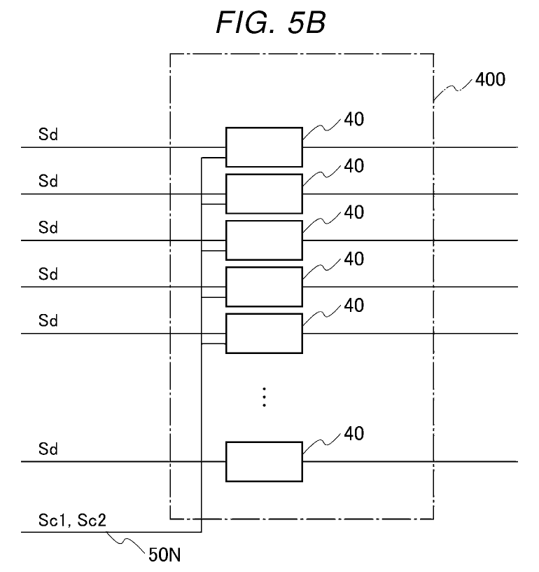

FIG. 5A is a block diagram illustrating a part of the configuration of the non-volatile memory 2. Hereinafter, data transmission and reception between the input and output circuit 22 and the sense amplifier 31 in the non-volatile memory 2 will be described with reference to FIG. 5A.

The input and output circuit 22 transmits and receives the write data and the read data to and from the sense amplifier 31 via the bidirectional data bus YIO. The bidirectional data bus YIO has a configuration in which the plurality of data wirings connected between the input and output circuit 22 and the sense amplifier 31 are arranged adjacent to one another without being shielded. The bidirectional data bus YIO includes, for example, about several tens to 200 data wirings. By not shielding the data wirings, an increase in an area of a chip on which the non-volatile memory 2 is formed can be prevented.

The sense amplifier 31 includes a sense amplifier unit 31A connected to bit lines BL0 to BLm, a data register 31B connected to the sense amplifier unit 31A, and a data multiplexer 31C connected to the data register 31B. The number of bit lines is, for example, about 130000. The sense amplifier unit 31A senses the read data read to the bit line and transfers the write data to the memory cell via the bit line. The data register 31B stores the read data and the write data. The data multiplexer 31C selects data propagating through the signal lines forming the bidirectional data bus YIO from among data propagating through the bit lines BL0 to BLm.

The input and output circuit 22 may include a conversion circuit 221 that converts a bus width. The conversion circuit 221 converts a bus width of the bidirectional data bus YIO including, for example, 128 bit lines to that of a bus including eight signal lines through which the signal DQ <7:0> propagates. The conversion circuit 221 may be, for example, a first in first out (FIFO) circuit. For example, the second power supply voltage VccQ (for example, 1.2 V) operates between the sense amplifier 31 and the input and output circuit 22 and between the input and output circuit 22 and the memory controller 1.

The control signal transmission circuit 50 is, for example, a part of the sequencer 27 illustrated in FIG. 2. The control signal transmission circuit 50 generates a clock signal CLK based on, for example, the signals /RE and RE supplied from the memory controller 1 in the data-out operation.

As illustrated in FIG. 5A, a relay area 400 is provided in a path of the bidirectional data bus YIO. As illustrated in FIG. 5B, a plurality of bidirectional transmission circuits 40 are provided in the relay area 400. The bidirectional transmission circuits 40 are provided respectively for each of the plurality of data wirings included in the bidirectional data bus YIO. A first switching signal Sc1 and a second switching signal Sc2 are commonly supplied from the sequencer 27 to each of the plurality of bidirectional transmission circuits 40 via a control signal wiring 50N. It is noted that a plurality of the relay areas 400 may be provided in the path of the bidirectional data bus YIO.

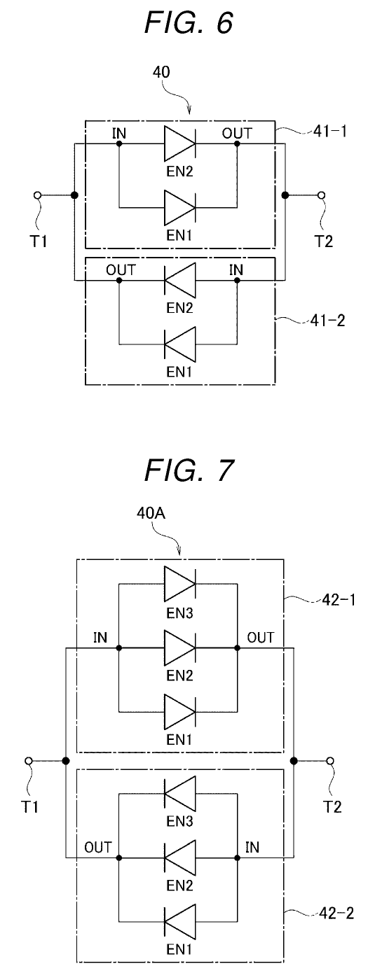

FIG. 6 is a circuit diagram illustrating a configuration example of the bidirectional transmission circuit 40. Each of the data wirings forming the bidirectional data bus YIO is implemented by connecting a corresponding one of the plurality of bidirectional transmission circuits 40 in series. As illustrated in FIG. 6, the bidirectional transmission circuit 40 includes a first repeater buffer circuit 41-1 and a second repeater buffer circuit 41-2 connected in parallel with the first repeater buffer circuit 41-1.

An input terminal IN of the first repeater buffer circuit 41-1 and an output terminal OUT of the second repeater buffer circuit 41-2 are connected to a first terminal T1. An output terminal OUT of the first repeater buffer circuit 41-1 and an input terminal IN of the second repeater buffer circuit 41-2 are connected to a second terminal T2. Accordingly, the bidirectional transmission circuit 40 can bidirectionally transmit data between the first terminal T1 and the second terminal T2.

As illustrated in FIG. 6, each of the first repeater buffer circuit 41-1 and the second repeater buffer circuit 41-2 includes a first repeater buffer EN1 and a second repeater buffer EN2 connected in parallel to the first repeater buffer EN1. It is noted that FIG. 6 illustrates a case in which two repeater buffers EN1 and EN2 are connected in parallel in each of the first repeater buffer circuit 41-1 and the second repeater buffer circuit 41-2, but the embodiment is not limited thereto.

For example, as in a bidirectional transmission circuit 40A illustrated in FIG. 7, each of a first repeater buffer circuit 42-1 and a second repeater buffer circuit 42-2 may include three repeater buffers EN1, EN2, and EN3 connected in parallel. Each repeater buffer circuit may include four or more repeater buffers connected in parallel.

In the following description, for the sake of simplicity, a case in which two repeater buffers EN1 and EN2 are connected in parallel in each of the first repeater buffer circuit 41-1 and the second repeater buffer circuit 41-2 will be described as an example. When there is no need to distinguish the first repeater buffer circuit 41-1 and the second repeater buffer circuit 41-2, they are simply referred to as repeater buffer circuits 41. When there is no need to distinguish the first repeater buffer EN1 and the second repeater buffer EN2, they are simply referred to as repeater buffers EN.

The repeater buffer EN is a three-state buffer having three types of output states. In the repeater buffer EN, an operation of the repeater buffer EN is switched between enabled and disabled depending on whether the switching signal input to a control terminal is "enabled" or "disabled".

When the switching signal is "enabled" (for example, at the H level), the operation of the repeater buffer EN is enabled. That is, when a data signal input to the input terminal IN is at the H level, a signal at the H level is output to the output terminal OUT, and when the data signal input to the input terminal IN is at the L level, a signal at the L level is output to the output terminal OUT.

When the switching signal is "invalid" (for example, at the L level), the operation of the repeater buffer EN is invalid. That is, the output terminal OUT is in a high impedance state regardless of whether the data signal input to the input terminal IN is at the H level or the L level. The first repeater buffer EN1 and the second repeater buffer EN2 of the first repeater buffer circuit 41-1 and the first repeater buffer EN1 and the second repeater buffer EN2 of the second repeater buffer circuit 41-2 can be independently controlled by the switching signal from the sequencer 27.

When the data signal is transmitted through each of the data wirings implemented by connecting a corresponding one of the plurality of bidirectional transmission circuits 40 in series, the sequencer 27 controls each bidirectional transmission circuit 40 as follows. That is, the first repeater buffers EN1 of the first repeater buffer circuits 41-1 are controlled by a common first switching signal, and the second repeater buffers EN2 of the first repeater buffer circuits 41-1 are controlled by a common second switching signal. Similarly, the first repeater buffers EN1 of the second repeater buffer circuits 41-2 are controlled by a common third switching signal, and the second repeater buffers EN2 of the second repeater buffer circuits 41-2 are controlled by a common fourth switching signal.

By implementing the repeater buffer circuit 41 with a plurality of repeater buffers connected in parallel, for example, by the first repeater buffer EN1 and the second repeater buffer EN2, the repeater buffer circuit 41 can support a plurality of transmission speeds. For example, a transmission speed of the first repeater buffer EN1 is designed to be 3.6 Gbps, and a transmission speed of the second repeater buffer EN2 is designed to be 1.2 Gbps.

By enabling the operations of both the first repeater buffer EN1 and the second repeater buffer EN2, the transmission speed of the repeater buffer circuit 41 can be set to 4.8 Gbps. By enabling the operation of the first repeater buffer EN1 and disabling the operation of the second repeater buffer EN2, it is possible to set the transmission speed of the repeater buffer circuit 41 to 3.6 Gbs and to prevent an off-leakage current from flowing through the second repeater buffer EN2. By disabling the operation of the first repeater buffer EN1 and enabling the operation of the second repeater buffer EN2, it is possible to set the transmission speed of the repeater buffer circuit 41 to 1.2 Gbs and to prevent an off-leakage current from flowing through the first repeater buffer EN1. When the repeater buffer circuit 41 is not used, off-leakage currents of both the first repeater buffer EN1 and the second repeater buffer EN can be prevented by disabling the operations of both the first repeater buffer EN1 and the second repeater buffer EN. In this way, by disabling an operation of an unused buffer, the off-leakage current of the repeater buffer circuit 41 can be prevented.

Although the description is made in which the transmission speeds of the first repeater buffer EN1 and the second repeater buffer EN2 are different from each other, the transmission speeds of the first repeater buffer EN1 and the second repeater buffer EN2 may be the same.

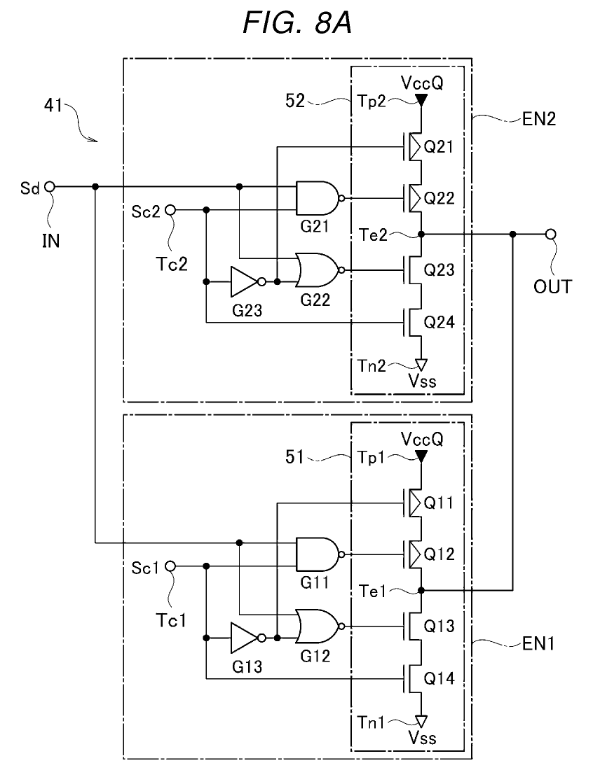

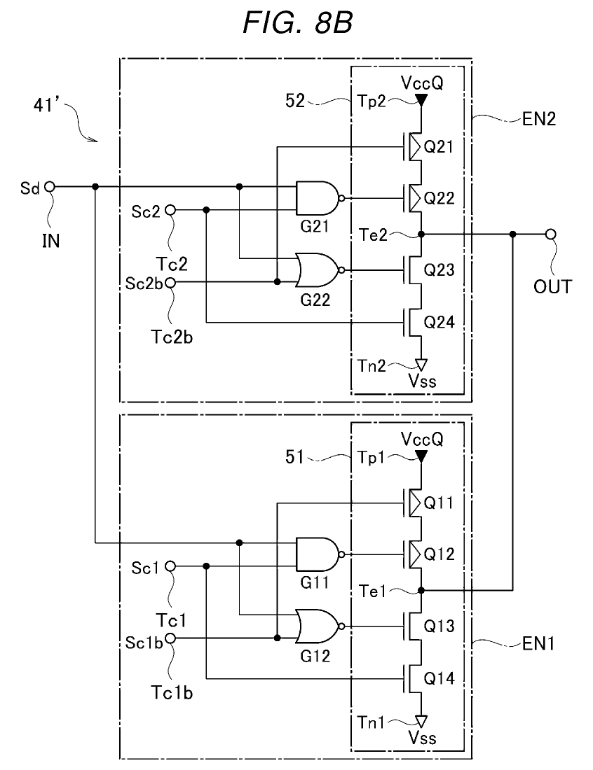

Next, a configuration of the repeater buffer circuit 41 will be described in more detail with reference to FIG. 8A. FIG. 8A is a circuit diagram of the repeater buffer circuit 41 according to a first configuration example. The repeater buffer circuit 41 includes the input terminal IN, the output terminal OUT, and the first repeater buffer EN1 and the second repeater buffer EN2 connected in parallel between the input terminal IN and the output terminal OUT. A data signal Sd is input to the input terminal IN. In the repeater buffer circuit 41 according to the first configuration example, the first repeater buffer EN1 and the second repeater buffer EN2 have the same circuit configuration in terms of function. Meanwhile, the size of the first repeater buffer EN1 and the size of the second repeater buffer EN2 may be the same or different depending on the target drivability. For example, the size of the first repeater buffer EN1 may be set to be larger than the size of the second repeater buffer EN2 so that the first repeater buffer EN1 has a higher drivability and transmission speed than that of the second repeater buffer EN2. More specifically, the first repeater buffer EN1 may have a size suitable for 3.6 Gbps, and the second repeater buffer EN2 may have a size suitable for 1.2 Gbps.

The first repeater buffer EN1 includes a first transistor circuit 51, a first control terminal Tc1, a first NAND gate G11, a first NOR gate G12, and a first inverter G13. The first switching signal Sc1 is transmitted from the sequencer 27 to the first control terminal Tc1. The first NAND gate G11, the first NOR gate G12, and the first inverter G13 serve as a control unit of the first repeater buffer EN1. The first transistor circuit 51 serves as a drive unit of the first repeater buffer EN1.

The second repeater buffer EN2 includes a second transistor circuit 52, a second control terminal Tc2, a second NAND gate G21, a second NOR gate G22, and a second inverter G23. The second switching signal Sc2 is transmitted from the sequencer 27 to the second control terminal Tc2. The second NAND gate G21, the second NOR gate G22, and the second inverter G23 serve as a control unit of the second repeater buffer EN2. The second transistor circuit 52 serves as a drive unit of the second repeater buffer EN2.

In the first transistor circuit 51, a series circuit of a first transistor Q11 and a second transistor Q12 on a high side and a series circuit of a third transistor Q13 and a fourth transistor Q14 on a low side are connected in series. The first transistor Q11 and the second transistor Q12 on the high side are implemented by P-channel MOSFETs. The third transistor Q13 and the fourth transistor Q14 on the low side are implemented by N-channel MOSFETs.

The second transistor circuit 52 is implemented similarly to the first transistor circuit 51. That is, in the second transistor circuit 52, a series circuit of a fifth transistor Q21 and a sixth transistor Q22 on the high side and a series circuit of a seventh transistor Q23 and an eighth transistor Q24 on the low side are connected in series. The fifth transistor Q21 and the sixth transistor Q22 on the high side are implemented by P-channel MOSFETs. The seventh transistor Q23 and the eighth transistor Q24 on the low side are implemented by N-channel MOSFETs.

For example, the transmission speed of the first repeater buffer EN1 can be set by the first transistor circuit 51, and the transmission speed of the second repeater buffer EN2 can be set by the second transistor circuit 52.

In the first transistor circuit 51, a drain of the first transistor Q11 is connected to a first positive power supply terminal Tp1. The first positive power supply terminal Tp1 has a voltage of the second power supply voltage VccQ (for example, 1.2 V). A source of the first transistor Q11 is connected to a drain of the second transistor Q12. A source of the second transistor Q12 is connected to a drain of the third transistor Q13. A connection point between the source of the second transistor Q12 and the drain of the third transistor Q13 serves as a first buffer output terminal Te1 and is connected to the output terminal OUT. A source of the third transistor Q13 is connected to a drain of the fourth transistor Q14. A source of the fourth transistor Q14 is connected to a first negative power supply terminal Tn1. The first negative power supply terminal Tn1 has a voltage of the ground voltage Vss (for example, 0 V).

In the second transistor circuit 52, a drain of the fifth transistor Q21 is connected to a second positive power supply terminal Tp2. The second positive power supply terminal Tp2 has a voltage of the second power supply voltage VccQ (for example, 1.2 V). A source of the fifth transistor Q21 is connected to a drain of the sixth transistor Q22. A source of the sixth transistor Q22 is connected to a drain of the seventh transistor Q23. A connection point between the source of the sixth transistor Q22 and the drain of the seventh transistor Q23 is a second buffer output terminal Te2 and is connected to the output terminal OUT. A source of the seventh transistor Q23 is connected to a drain of the eighth transistor Q24. A source of the eighth transistor Q24 is connected to a second negative power supply terminal Tn2. The second negative power supply terminal Tn2 has a voltage of the ground voltage Vss (for example, 0 V).

In the first repeater buffer EN1, the input terminal IN is connected to a first input terminal of the first NAND gate G11 and a first input terminal of the first NOR gate G12. The first control terminal Tc1 is connected to a second input terminal of the first NAND gate G11 and a gate of the fourth transistor Q14. The first control terminal Tc1 is connected to a second input terminal of the first NOR gate G12 and a gate of the first transistor Q11 via the first inverter G13. An output terminal of the first NAND gate G11 is connected to a gate of the second transistor Q12. An output terminal of the first NOR gate G12 is connected to a gate of the third transistor Q13.

In the second repeater buffer EN2, the input terminal IN is connected to a first input terminal of the second NAND gate G21 and a first input terminal of the second NOR gate G22. The second control terminal Tc2 is connected to a second input terminal of the second NAND gate G21 and a gate of the eighth transistor Q24. The second control terminal Tc2 is connected to a second input terminal of the second NOR gate G22 and a gate of the fifth transistor Q21 via the second inverter G23. An output terminal of the second NAND gate G21 is connected to a gate of the sixth transistor Q22. An output terminal of the second NOR gate G22 is connected to a gate of the seventh transistor Q23.

When the first switching signal Sc1 input to the first control terminal Tc1 is at the H level, the operation of the first repeater buffer EN1 is enabled. That is, the first repeater buffer EN1 outputs a signal at the H level to the output terminal OUT when the data signal Sd input to the input terminal IN is at the H level, and outputs a signal at the L level to the output terminal OUT when the data signal Sd input to the input terminal IN is at the L level.

More specifically, when the first switching signal Sc1 is at the H level, the first transistor Q11 and the fourth transistor Q14 are turned on. When the data signal Sd is at the H level, the second transistor Q12 is turned on since an output of the first NAND gate G11 is at the L level, and the third transistor Q13 is turned off since an output of the first NOR gate is at the L level. Therefore, a signal at the H level is output to the output terminal OUT. On the other hand, when the data signal Sd is at the L level, the second transistor Q12 is turned off since the output of the first NAND gate G11 is at the H level, and the third transistor Q13 is turned on since the output of the first NOR gate is at the H level. Therefore, a signal at the L level is output to the output terminal OUT.

When the first switching signal Sc1 input to the first control terminal Tc1 is at the L level, the operation of the first repeater buffer EN1 is disabled. That is, when the first switching signal Sc1 is at the L level, the first transistor Q11 and the fourth transistor Q14 are turned off. Regardless of whether the data signal Sd is at the H level or the L level, since the output of the first NAND gate G11 is at the H level, the second transistor Q12 is turned off, and since the output of the first NOR gate G12 is at the L level, the third transistor Q13 is turned off. Therefore, the first buffer output terminal Te1 is in a high impedance state, and the off-leakage current of the first repeater buffer EN1 is prevented. That is, in the first repeater buffer EN1, the first buffer output terminal Te1 is in a high impedance state regardless of whether the data signal Sd input to the input terminal IN is at the H level or the L level, and the off-leakage current of the first repeater buffer EN1 is prevented.

When the second switching signal Sc2 input to the second control terminal Tc2 is at the H level, the operation of the second repeater buffer EN2 is enabled. That is, similarly to the operation of the first repeater buffer EN1, the second repeater buffer EN2 outputs a signal at the H level to the output terminal OUT when the data signal Sd is at the H level, and outputs a signal at the L level to the output terminal OUT when the data signal Sd is at the L level.

When the second switching signal Sc2 input to the second control terminal Tc1 is at the L level, the operation of the second repeater buffer EN2 is disabled. That is, in the second repeater buffer EN2, the second buffer output terminal Te2 is in the high impedance state regardless of whether the data signal Sd input to the input terminal IN is at the H level or the L level, and the off-leakage current of the second repeater buffer EN2 is prevented.

In the repeater buffer circuit 41 according to the first configuration example, the first inverter G13 may be omitted, and a complementary signal (inverted signal) of the first switching signal Sc1 may be input from the sequencer 27. The second inverter G23 may be omitted, and a complementary signal (inverted signal) of the second switching signal Sc2 may be input from the sequencer 27.

For example, as in a repeater buffer circuit 41' according to a modification of the first configuration example illustrated in FIG. 8B, the first inverter G13 and the second inverter G23 are removed from the configuration illustrated in FIG. 8A. An inverted signal Sc1b of the first switching signal Sc1 is input from the sequencer 27 to the second input terminal of the first NOR gate G12 via a third control terminal Tc1b. An inverted signal Sc2b of the second switching signal Sc2 is input from the sequencer 27 to the second input terminal of the second NOR gate G22 via a fourth control terminal Tc2b.

The repeater buffer circuit 41' according to the modification of the first configuration example implemented as described above operates similarly to the repeater buffer circuit 41 according to the first configuration example. Therefore, the description of the operation of the repeater buffer circuit 41' according to the modification of the first configuration example will be omitted. With the configuration of the repeater buffer circuit 41' according to the modification of the first configuration example, it is possible to reduce a large area of the relay area 400 as a whole as compared with that of the repeater buffer circuit 41 according to the first configuration example.

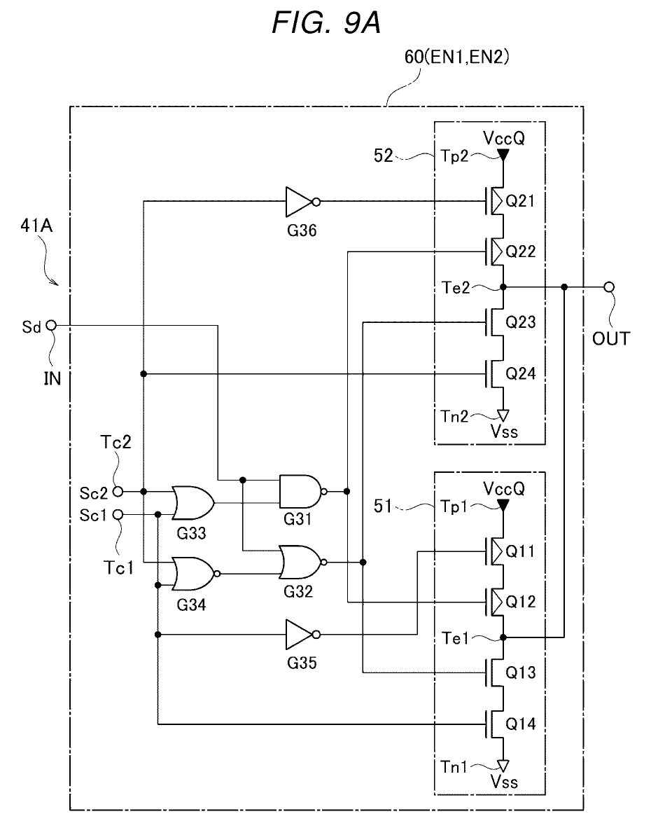

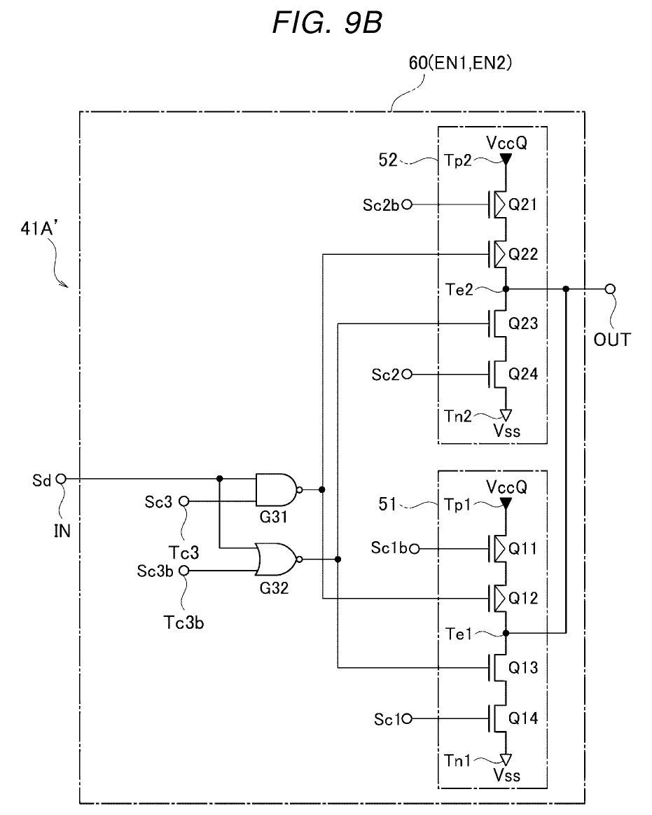

FIG. 9A is a circuit diagram of a repeater buffer circuit 41A according to a second configuration example. The repeater buffer circuit 41A includes the input terminal IN, the output terminal OUT, and a buffer circuit 60 connected in parallel between the input terminal IN and the output terminal OUT. The buffer circuit 60 performs the same operation as the first repeater buffer EN1 and the second repeater buffer EN2 according to the first configuration example.

The buffer circuit 60 includes the first transistor circuit 51, the second transistor circuit 52, a NAND gate G31, a NOR gate G32, an OR gate G33, a NOR gate G34, an inverter G35, and an inverter G36. Since the first transistor circuit 51 and the second transistor circuit 52 are the same as the repeater buffer circuit 41 according to the first configuration example, detailed description thereof will be omitted.

The first transistor circuit 51 corresponds to the drive unit of the first repeater buffer EN1. The second transistor circuit 52 corresponds to the drive unit of the second repeater buffer EN2. The NAND gate G31, the NOR gate G32, the OR gate G33, the NOR gate G34, the inverter G35, and the inverter G36 serve as common control units of the first repeater buffer EN1 and the second repeater buffer EN2.

The input terminal IN is connected to a first input terminal of the NAND gate G31 and a first input terminal of the NOR gate G32. The first control terminal Tc1 is connected to a first input terminal of the OR gate G33, a first input terminal of the NOR gate G34, and the gate of the fourth transistor Q14. The first control terminal Tc1 is connected to the gate of the first transistor Q11 via the inverter G35. The second control terminal Tc2 is connected to a second input terminal of the OR gate G33, a second input terminal of the NOR gate G34, and the gate of the eighth transistor Q24. The second control terminal Tc2 is connected to the gate of the fifth transistor Q21 via the inverter G36.

An output terminal of the NAND gate G31 is connected to the gates of the second transistor Q12 and the sixth transistor Q22. An output terminal of the NOR gate G32 is connected to the gates of the third transistor Q13 and the seventh transistor Q23.

When the first switching signal Sc1 is at the H level, the first transistor Q11 and the fourth transistor Q14 are turned on, an output of the OR gate G33 is at the H level, and an output of the NOR gate G34 is at the L level. When the data signal Sd is at the H level, since the output of the NAND gate G31 is at the L level, the second transistor Q12 is turned on, and since the output of the NOR gate G34 is at the L level, the third transistor Q13 is turned off. Therefore, the first buffer output terminal Te1 connected to the output terminal OUT is at the H level. When the data signal Sd is at the L level, since the output of the NAND gate G31 is at the H level, the second transistor Q12 is turned off, and since the output of the NOR gate G34 is at the H level, the third transistor Q13 is turned on. Therefore, the first buffer output terminal Te1 connected to the output terminal OUT is at the L level.

When the first switching signal Sc1 is at the L level, the first transistor Q11 and the fourth transistor Q14 are turned off. Regardless of whether the data signal Sd is at the H level or the L level, since the output of the NAND gate G31 is at the H level, the second transistor Q12 is turned off, and since the output of the NOR gate G32 is at the L level, the third transistor Q13 is turned off. Therefore, the first buffer output terminal Te1 is in a high impedance state, and the off-leakage current of the first transistor circuit 51 is prevented.

When the second switching signal Sc2 is at the H level, the fifth transistor Q21 and the eighth transistor Q24 are turned on, the output of the OR gate G33 is at the H level, and the output of the NOR gate G34 is at the L level. When the data signal Sd is at the H level, since the output of the NAND gate G31 is at the L level, the sixth transistor Q22 is turned on, and since the output of the NOR gate G34 is at the L level, the seventh transistor Q23 is turned off. Therefore, the second buffer output terminal Te2 connected to the output terminal OUT is at the H level. When the data signal Sd is at the L level, since the output of the NAND gate G31 is at the H level, the sixth transistor Q22 is turned off, and since the output of the NOR gate G34 is at the H level, the seventh transistor Q23 is turned on. Therefore, the second buffer output terminal Te2 connected to the output terminal OUT is at the L level.

When the second switching signal Sc2 is at the L level, the fifth transistor Q21 and the eighth transistor Q24 are turned off. Regardless of whether the data signal Sd is at the H level or the L level, since the output of the NAND gate G31 is at the H level, the sixth transistor Q22 is turned off, and since the output of the NOR gate G32 is at the L level, the seventh transistor Q23 is turned off. Therefore, the second buffer output terminal Te2 is in a high impedance state, and the off-leakage current of the second transistor circuit 52 is prevented.

In the repeater buffer circuit 41A according to the second configuration example, the inverter G35 may be omitted, and a complementary signal (inverted signal) of the first switching signal Sc1 may be input from the sequencer 27. The inverter G36 may be omitted, and a complementary signal (inverted signal) of the second switching signal Sc2 may be input from the sequencer 27.

For example, as in a repeater buffer circuit 41A' according to a modification of the second configuration example illustrated in FIG. 9B, the OR gate G33, the NOR gate G34, the inverter G35, and the inverter G36 are removed from the configuration illustrated in FIG. 9A. A third switching signal Sc3 is input from the sequencer 27 to a second input terminal of the NAND gate G31 via a control terminal Tc3. The third switching signal Sc3 is an OR signal of the first switching signal Sc1 and the second switching signal Sc2. An inverted signal Sc3b of the third switching signal is input from the sequencer 27 to a second input terminal of the NOR gate G32 via a control terminal Tc3b.

The inverted signal Sc1b of the first switching signal Sc1 is input from the sequencer 27 to the gate of the first transistor Q11. The first switching signal Sc1 is input from the sequencer 27 to the gate of the fourth transistor Q14. The inverted signal Sc2b of the second switching signal Sc2 is input from the sequencer 27 to the gate of the fifth transistor Q21. The second switching signal Sc2 is input from the sequencer 27 to the gate of the eighth transistor Q24.

The repeater buffer circuit 41A' according to the modification of the second configuration example implemented as described above operates similarly to the repeater buffer circuit 41A according to the second configuration example. Therefore, the description of the operation of the repeater buffer circuit 41A' according to the modification of the second configuration example will be omitted. With the configuration of the repeater buffer circuit 41A' according to the modification of the second configuration example, it is possible to reduce a large area of the relay area 400 as a whole as compared with that of the repeater buffer circuit 41A according to the second configuration example.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
an input and output pad;
a memory cell array including a plurality of memory cells;
an input and output circuit provided between the input and output pad and the memory cell array;
a sense amplifier connected to the memory cell array;
a bidirectional data bus including a plurality of data wirings connecting the input and output circuit and the sense amplifier; and
a sequencer configured to control the input and output circuit, the memory cell array, the sense amplifier, and the bidirectional data bus, wherein
each of the data wirings is provided with a repeater buffer circuit,
the repeater buffer circuit includes a first repeater buffer and a second repeater buffer connected in parallel to the first repeater buffer, and
the sequencer is configured to transmit a switching signal for independently controlling each of the first repeater buffer and the second repeater buffer to be enabled or disabled.

2. The semiconductor storage device according to claim 1, wherein
the repeater buffer circuit operates at a first transmission speed when both the first repeater buffer and the second repeater buffer are enabled, at a second transmission speed when the first repeater buffer is enabled and the second repeater buffer is disabled, and at a third transmission speed when the first repeater buffer is disabled and the second repeater buffer is enabled.

3. The semiconductor storage device according to claim 2, wherein
the first repeater buffer and the second repeater buffer operate at different transmission speeds.

4. The semiconductor storage device according to claim 2, wherein
the first repeater buffer and the second repeater buffer operate at the same transmission speed.

5. The semiconductor storage device according to claim 1, wherein
the repeater buffer circuit further includes a third repeater buffer connected in parallel to the first repeater buffer and the second repeater buffer.

6. The semiconductor storage device according to claim 1, wherein
the first repeater buffer and the second repeater buffer are repeater buffers having a common circuit configuration,
the repeater buffer circuit includes a control circuit and a drive circuit, and
the control circuit controls the drive circuit according to an input signal and the switching signal.

7. The semiconductor storage device according to claim 6, wherein
the drive circuit includes a first series circuit on a high side in which a first transistor and a second transistor are connected in series and a second series circuit on a low side in which a third transistor and a fourth transistor are connected are connected in series, and
an output terminal of the repeater buffer circuit is connected to node between the first series circuit and the second series circuit.

8. The semiconductor storage device according to claim 7, wherein
the first transistor and the second transistor are P-channel MOSFETs, and the third transistor and the fourth transistor are N-channel MOSFETs.

9. The semiconductor storage device according to claim 8, wherein
the switching signal is input to a gate of the fourth transistor, and a complementary signal of the switching signal is input to a gate of the first transistor.

10. The semiconductor storage device according to claim 1, wherein
the first repeater buffer and the second repeater buffer are repeater buffers having a common circuit configuration, and
the first repeater buffer and the second repeater buffer each include a drive circuit and a control circuit that controls the drive circuit according to an input signal and the switching signal.

11. The semiconductor storage device according to claim 1, wherein
the first repeater buffer and the second repeater buffer are repeater buffers having a common circuit configuration, and
the first repeater buffer and the second repeater buffer each include a drive circuit and share one control circuit that controls the drive circuits of both the first repeater buffer and the second repeater buffer according to an input signal and the switching signal.

12. A semiconductor storage device comprising:
a memory cell array;
a data register for storing data read from the memory cell array or data to be written to the memory cell array;
an input/output circuit through which the data read from the memory cell array and stored in the data register is output and through which the data to be written to the memory cell array is input;
a bidirectional data bus between the input/output circuit and the data register, the bidirectional data bus including a plurality of data wirings, each of which is provided with a repeater buffer circuit, wherein
the repeater buffer circuit includes a first repeater buffer and a second repeater buffer connected in parallel to the first repeater buffer, and
the first repeater buffer and the second repeater buffer are independently controlled to be enabled or disabled.

13. The semiconductor storage device according to claim 12, wherein the first repeater buffer and the second repeater buffer are controlled to be enabled to operate the repeater buffer circuit at a transmission speed that is equal to a sum of a first transmission speed of the first repeater buffer and a second transmission speed of the second repeater buffer.

14. The semiconductor storage device according to claim 12, wherein the first repeater buffer is controlled to be enabled and the second repeater buffer is controlled to be disabled to operate the repeater buffer circuit at a transmission speed that is equal to a transmission speed of the first repeater buffer.

15. The semiconductor storage device according to claim 12, wherein the first repeater buffer is controlled to be disabled and the second repeater buffer is controlled to be enabled to operate the repeater buffer circuit at a transmission speed that is equal to a transmission speed of the second repeater buffer.

16. The semiconductor storage device according to claim 12, wherein the first repeater buffer and the second repeater buffer each include a drive circuit and a control circuit that controls the drive circuit.

17. The semiconductor storage device according to claim 12, wherein the first repeater buffer and the second repeater buffer each include a drive circuit and share a control circuit that controls the drive circuits of both the first repeater buffer and the second repeater buffer.

18. The semiconductor storage device according to claim 12, wherein the repeater buffer circuit further includes a third repeater buffer connected in parallel to the first repeater buffer and the second repeater buffer, and
the first, second, and third repeater buffers are independently controlled to be enabled or disabled.

19. The semiconductor storage device according to claim 18, wherein the first, second, and third repeater buffers have a common circuit configuration.
